(19) United States
(12) Patent Application Publication
(10) Pub. No.: US 2026/0368392 A1
(43) Pub. Date: Nov. 19, 2026

(54) METHOD AND SYSTEM FOR AUTOMATICALLY GENERATING PEANUT SAMPLES BASED ON MULTISOURCE TWDTW

(71) Applicant: INSTITUTE OF AGRICULTURAL RESOURCES AND REGIONAL PLANNING, CAAS, BEIJING (CN)

(72) Inventors: HONGWEI ZHAO, BEIJING (CN); HUALIN CAO, BEIJING (CN); RUILIN YU, BEIJING (CN); JIA LIU, BEIJING (CN)

(21) Appl. No.: 19/369,777

(22) Filed: Oct. 27, 2025

Related U.S. Application Data
(63) Continuation of application No. PCT/CN2025/115648, filed on Aug. 19, 2025.

(30) Foreign Application Priority Data
May 16, 2025 (CN) 202510629673.1

(51) Int. Cl. G06F 30/20

(52) U.S. Cl. CPC G06F 30/20

(57) ABSTRACT

The invention provides a method and system for automatically generating peanut samples using multisource remote-sensing data and the Time Weighted Dynamic Time Warping (TWDTW) algorithm. The method includes: establishing and splicing standard phenological curves from various data sources, including SAR and multi-spectral to create a standard multisource feature phenological curve; calculating cumulative distances between multisource feature phenological curves of sample points under detection and the standard multisource feature phenological curve; and determining a crop type of the sample points under detection to obtain sample data of the crop type. The method for automatically generating peanut samples based on multisource remote-sensing data and growth period features establishes the standard multisource feature phenological curve, calculates the cumulative distances and improves the recognition accuracy of peanuts in the early phase by machine learning, thus reducing the peanut sample acquisition difficulty and cost.

### BACKGROUND OF THE INVENTION

### 1. Technical Field

The invention belongs to the technical field of remote sensing in agriculture, and particularly, relates to a method and system for automatically generating peanut samples based on multisource TWDTW.

### 2. Description of Related Art

Peanuts are an important oil crop and economic crop, and timely and accurate spatial distribution information of peanuts is of great importance for agricultural management, food security and market forecast and decision-making of oil crops. Remote sensing is an effective tool for crop type mapping, and supervised classification methods such as machine learning and deep learning are important methods for crop type mapping. However, the performance of these supervised classification methods highly depends on the number and quality of training samples. Although traditional field investigation provides the most direct and reliable sample collection method, it is time-consuming and high in cost, particularly for large-area mapping of crops in the early phase. How to acquire sufficient samples in the early phase of the growth period of crops is the key to improving peanut mapping accuracy and timeliness.

At present, the sample automatic-generation technique combining remote-sensing time series data and phenological phases of crops has become an effective means for sample acquisition. However, most methods mainly use optical data features and separately extract bulk grains (wheat and corn) for study. In complex planting regions and growth seasons, the difference in electromagnetic radiation spectral features of crops is often more significant, which poses a challenge to early recognition of peanuts, and particularly, the similarity in growth period of peanuts and root-stem crops makes the recognition more difficult.

### BRIEF SUMMARY OF THE INVENTION

To solve the above-mentioned technical problems, the invention provides a method and system for automatically generating peanut samples based on multisource TWDTW and an electronic device.

In a first aspect, the invention provides a method for automatically generating peanut samples based on multisource TWDTW, including:
establishing a plurality of phenological zones according to areas of all types of crops in a region, and establishing standard phenological curves corresponding to features of the crops in the phenological zones according to field investigation sample point data and preprocessed remote-sensing image time series data;
splicing the standard phenological curves of different features in the same region and time period to form a standard multisource feature phenological curve;
acquiring land cover data of a sample generation region, randomly generating sample points in a land plot, and calculating time series data of the sample points under detection to obtain multisource feature phenological curves of the sample points under detection;
calculating cumulative distances between multisource feature phenological curves of all the types of crops and the standard multisource feature phenological curve, and determining threshold ranges corresponding to the cumulative distances between the multisource feature phenological curves of all the types of crops and the standard multisource feature phenological curve;
calculating cumulative distances between the multisource feature phenological curves of the sample points under detection and the standard multisource feature phenological curve; and
determining a crop type of the sample points under detection according to the cumulative distances and the threshold ranges to obtain sample data of the crop type.

In a second aspect, the invention provides a system for automatically generating peanut samples based on multisource TWDTW, including a standard phenological curve establishing unit, a splicing unit, a multisource feature phenological curve generating unit, a first data processing unit, a second data processing unit and an output unit.

The standard phenological curve establishing unit is configured to establish a plurality of phenological zones according to areas of all types of crops in a region and establish standard phenological curves corresponding to features of the crops in the phenological zones according to field investigation sample point data and preprocessed remote-sensing image time series data.

The splicing unit is configured to splice the standard phenological curves of different features in the same region and time period to form a standard multisource feature phenological curve.

The multisource feature phenological curve generating unit is configured to acquire land cover data of a sample generation region, randomly generate sample points in a land plot and calculate time series data of the sample points under detection to obtain multisource feature phenological curves of the sample points under detection.

The first data processing unit is configured to calculate cumulative distances between multisource feature phenological curves of all the types of crops and the standard multisource feature phenological curve and determine threshold ranges corresponding to the cumulative distances between the multisource feature phenological curves of all the types of crops and the standard multisource feature phenological curve.

The second data processing unit is configured to calculate cumulative distances between the multisource feature phenological curves of the sample points under detection and the standard multisource feature phenological curve.

The output unit is configured to determine a crop type of the sample points under detection according to the cumulative distances and the threshold ranges to obtain sample data of the crop type.

Based on the above technical solution, the invention may be improved as follows.

Further, the remote-sensing image time series data include Synthetic Aperture Radar (SAR) data, multi-spectral remote-sensing data and land cover data.

Further, preprocessing the remote-sensing image time series data of the crops includes: filtering the remote-sensing image time series data, transforming a coordinate system into a world geodetic system, and resampling an azimuth resolution and a range resolution of images to 10 m; performing time series smoothing by an S-G smoothing filter algorithm to remove thermal noise; performing radiation correction; and performing topographical correction by means of DEM data.

Further, the features of the crops include a band feature, a texture feature and a vegetation index feature.

Further, calculating cumulative distances between multisource feature phenological curves of all the types of crops and the standard multisource feature phenological curve includes: setting a time series of the multisource feature phenological curves of the crops as U, a length of the time series as m and an i^{th} feature as uᵢ, and setting a time series of the standard multisource feature phenological curve as V, a length of the time series as n and a j^{th} feature as vᵢ:

U={u₁,u₂, . . . ,uₘ}^{T};

V={v₁,v₂, . . . ,vₙ}^{T};
setting d_{i, j} as a time-weighted distance between the i^{th} feature and the j^{th} feature and D_{m×n} as a distance matrix between the i^{th} feature and the j^{th} feature:

D_{m×n}=(d_{i,j})_{m×n}
setting a time weight factor as w_{i, j}, g as a gain factor and c as a distance factor, wherein the distance factor is a difference in time series length between the i^{th} feature and the j^{th} feature, c=i−j and m, is a set ratio of series timespan:

$${d}_{i , j} = \vert {u}_{i} - {v}_{j} \vert + {w}_{i , j} ;$$

$${w}_{i , j} = \frac{1}{1 + {e}^{( - g ( c - {m}_{c} ) )}} ;$$

setting (i, j) as a node corresponding to the i^{th} feature and the j^{th} feature, (i+1, j) as a node corresponding to a (i+1)th feature and the j^{th} feature, (i, j+1) as a node corresponding to the i^{th} feature and a (j+1)^{th} feature, (i+1, j+1) as a node corresponding to the (i+1)^{th} feature and the (j+1)^{th} feature and a cumulative distance between U and V at the node (i, j) as φ(i, j), searching for a minimum cumulative distance, and setting a cumulative distance at a previous node as a minimum value of (i−1, j), (i, j−1) and (i−1, j−1):

φ(i,j)=d_{i,j}+min{φ(i−1,j),φ(i−1,j−1),φ(i,j−1)};
setting a minimum cumulative distance path as L:

max{m,n}≤L≤m+n−1.

Further, when the cumulative distances between the multisource feature phenological curves of all the types of crops and the standard multisource feature phenological curve are calculated, the cumulative distance corresponding to a k^{th} type of crops is φₖ, wₖ is a weight of the cumulative distance corresponding to the k^{th} type of crops, a total distance of the standard phenological curves of the crops in the corresponding phenological zones is φₛᵤₘ, and the weight of the cumulative distance corresponding to the k^{th} type of crops is determined by the total distance of the standard phenological curves of the crops in the corresponding phenological zones:

φₛᵤₘ=w₁*φ₁+w₂*φ₂+ . . . +wₖ*φₖ;

Distanceᵢ is set as a sum of cumulative distances between the standard phenological curves in an i^{th} phenological zone, and wᵢ is the weight of the cumulative distance corresponding to an i^{th} type of crops:

$${w}_{i} = \frac{{Distance}_{i}}{{\sum }_{i = 1} {Distance}_{i}} .$$

Further, the crop type of the sample points under detection is determined according to the cumulative distances and the threshold ranges to obtain preliminarily classified samples, and a time series of the sample generation region is resampled to be identical with a standard time series of the crops.

Further, a Manhattan distance between each preliminarily classified sample and a corresponding labelled crop is calculated; if the Manhattan distance is greater than a set threshold, the preliminarily classified sample is reserved; otherwise, the preliminarily classified sample is rejected; the Manhattan distance is set as MD, xᵢ a feature value of the time series of the sample generation region at a time i, yᵢ a feature value of the standard time series at the time i, and N is the number of data in the time series:

$$MD = {\sum }_{i = 1}^{N} \vert {x}_{i} - {y}_{i} \vert .$$

Further, before the Manhattan distance between each preliminarily classified sample and the corresponding labelled crop is calculated, the time series of the sample generation region is resampled to be identical with a standard time series of the crops.

The invention has the following beneficial effects: the invention provides the method for automatically generating peanut samples based on multisource remote-sensing data and growth period features, which establishes a standard multisource feature phenological curve, calculates cumulative distances between multisource feature phenological curves of sample points under detection and the standard multisource feature phenological curve, and improves the recognition accuracy of peanuts in the early phase by machine learning, thus reducing the peanut sample acquisition difficulty and cost.

### BRIEF DESCRIPTION OF THE SEVERAL VIEWS OF THE DRAWINGS

FIG. 1 illustrates a schematic diagram of a method for automatically generating peanut samples based on multisource TWDTW according to Embodiment 1 of the invention.

FIG. 2 illustrates a comparison graph before and after S-G smoothing filter.

FIG. 3 illustrates a multisource TWDTW zone chart, wherein (a) in FIG. 3 illustrates the multisource TWDTW zone chart, (b) in FIG. 3 illustrates NDVI curves of crops, (c) in FIG. 3 illustrates contrast curves, and (d) in FIG. 3 illustrates phenological curves in three phases of the growth period of crops.

FIG. 4 illustrates a schematic diagram of a system for automatically generating peanut samples based on multisource TWDTW according to Embodiment 2 of the invention.

### DETAILED DESCRIPTION OF THE INVENTION

To better clarify the purposes, technical solutions and advantages of the embodiments of the invention, the technical solutions in the embodiments of the invention are clearly and completely described in conjunction with accompanying drawings of the embodiments of the invention. Obviously, the embodiments described below are merely illustrative ones and are not all possible ones of the invention. Generally, components in the embodiments of the invention described and illustrated in the drawings may be arranged and designed according to different configurations.

### Embodiment 1

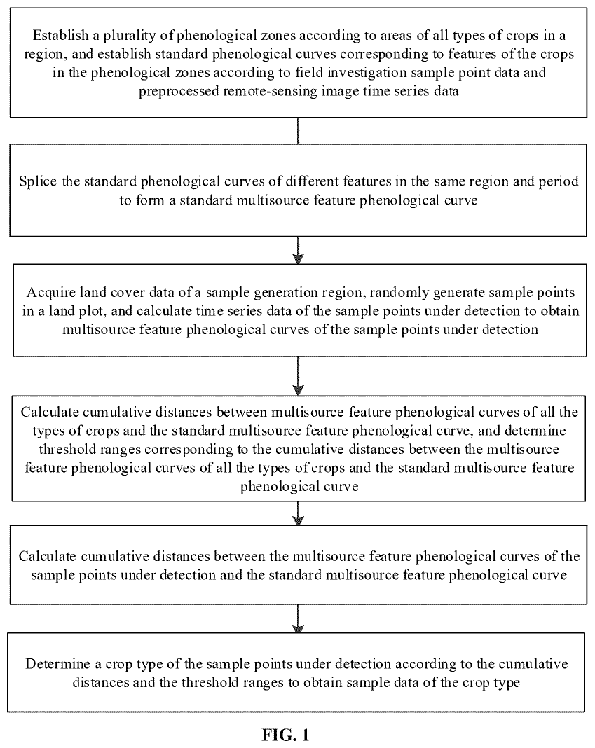

As an example, as shown in FIG. 1, to solve the above-mentioned technical problems, this embodiment provides a method for automatically generating peanut samples based on multisource TWDTW, including:
establishing a plurality of phenological zones according to areas of all types of crops in a region, and establishing standard phenological curves corresponding to features of the crops in the phenological zones according to field investigation sample point data and preprocessed remote-sensing image time series data;
splicing the standard phenological curves of different features in the same region and time period to form a standard multisource feature phenological curve;
acquiring land cover data of a sample generation region, randomly generating sample points in a land plot, and calculating time series data of the sample points under detection to obtain multisource feature phenological curves of the sample points under detection;
calculating cumulative distances between multisource feature phenological curves of all the types of crops and the standard multisource feature phenological curve, and determining threshold ranges corresponding to the cumulative distances between the multisource feature phenological curves of all the types of crops and the standard multisource feature phenological curve;
calculating cumulative distances between the multisource feature phenological curves of the sample points under detection and the standard multisource feature phenological curve; and
determining a crop type of the sample points under detection according to the cumulative distances and the threshold ranges to obtain sample data of the crop type.

In actual application, SAR data are a Sentinel-1 satellite-ground distance multi-look image set in the region. The image set includes 10 m, 25 m and 40 m spatial resolutions, four polarized band combinations and three imaging patterns, and only images with the scan pattern of Interferometric Wide Swath (IW) and the polarization pattern of Vertical-Horizontal polarization (VH) and Vertical-Vertical polarization (VV) are selected. The multi-spectral remote-sensing data are Sentinel-2 Multi-Spectral Instrument Level-2A (Sentinel-2MSI L2A) data, and bands required by experiments are visible light bands (B2-B4), infrared bands (B5-B7), near-infrared bands (B8 and B8A) and short wave infrared bands (B11 and B12), ten in total. The land cover data use ground crop sample data in a global land cover map with a resolution of 10 m as crop field sampling data, including longitude and latitude information and crop type labels.

Optionally, the remote-sensing image time series data include Synthetic Aperture Radar (SAR) data, multi-spectral remote-sensing data and land cover data.

Optionally, preprocessing the remote-sensing image time series data of the crops includes: filtering the remote-sensing image time series data, transforming a coordinate system into a world geodetic system, and resampling an azimuth resolution and a range resolution of images to 10 m; performing time series smoothing by an S-G smoothing filter algorithm to remove thermal noise; performing radiation correction; and performing topographical correction by means of DEM data.

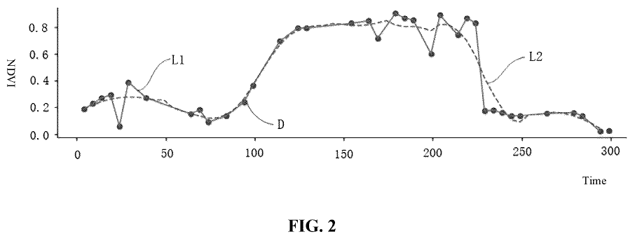

In actual application, after Sentinel-1 satellite remote-sensing images are acquired from a Google Earth Engine (GEE), the Sentinel-1 satellite remote-sensing images are filtered by the Lee-sigma algorithm to reduce or eliminate the error influence of speckle noise and reserve edge details of the images. Meanwhile, to facilitate registration of the Sentinel-1 satellite remote-sensing images and multi-spectral remote-sensing data heterogeneous images, the coordinate system of the Sentinel-1 satellite remote-sensing images needs to be transformed into the world geodetic system, and the azimuth resolution and the range resolution of the images are resampled to 10 m. Under the influence of the sun angle, the observation angle, the sensitivity of sensors, the sexual reflex of ground objects and aerosol, the Sentinel-1 satellite remote-sensing images and the multi-spectral remote-sensing data often include a great deal of noise, so Savitzky-Golay Smoothing Filter (S-G smoothing filter) is adopted for time series smoothing to better embody the variation trend reflected by data. As shown in FIG. 2, the abscissa axis is time (unit: day), the vertical axis is the normalized differential vegetation index (NDVI), D is original remote-sensing image time series data, L1 is a linear interpolation curve, and L2 is data subjected to S-G smoothing filter.

Optionally, the features of the crops include a band feature, a texture feature and a vegetation index feature.

The basic principle of Time Weighted Dynamic Time Warping (TWDTW) is to evaluate the similarity by finding the optimal alignment method of time series and calculating cumulative distances.

Optionally, calculating cumulative distances between multisource feature phenological curves of all the types of crops and the standard multisource feature phenological curve includes: setting a time series of the multisource feature phenological curves of the crops as U, a length of the time series as m and an i^{th} feature as uᵢ, and setting a time series of the standard multisource feature phenological curve as V, a length of the time series as n and a j^{th} feature as vᵢ.

U={u₁,u₂, . . . ,uₘ}^{T};

U={u₁,u₂, . . . ,uₘ}^{T};
setting d_{i, j} as a time-weighted distance between the i^{th} feature and the j^{th} feature and D_{m×n} as a distance matrix between the i^{th} feature and the j^{th} feature:

D_{m×n}=(d_{i,j})_{m×n};
setting a time weight factor as w_{i, j}, g as a gain factor and c as a distance factor, wherein the distance factor is a difference in time series length between the i^{th} feature and the j^{th} feature, c=i−j, and m, is a set ratio of series timespan:

$${d}_{i , j} = \vert {u}_{i} - {v}_{j} \vert + {w}_{i , j} ;$$

$${w}_{i , j} = \frac{1}{1 + {e}^{( - g ( c - {m}_{c} ) )}} ;$$

setting (i, j) as a node corresponding to the i^{th} feature and the j^{th} feature, (i+1, j) as a node corresponding to a (i+1)^{th} feature and the j^{th} feature, (i, j+1) as a node corresponding to the i^{th} feature and a (j+1)^{th} feature, (i+1, j+1) as a node corresponding to the (i+1)^{th} feature and the (j+1)^{th} feature and a cumulative distance between U and V at the node (i, j) as φ(i, j), searching for a minimum cumulative distance, and setting a cumulative distance at a previous node as a minimum value of (i−1, j), (i, j−1) and (i−1, j−1):

φ(i,j)=d_{i,j}+min{(i−1,j),φ(i−1,j−1),φ(i,j−1)};
setting a minimum cumulative distance path as L:

max{m,n}≤L≤m+n−1.

Optionally, when the cumulative distances between the multisource feature phenological curves of all the types of crops and the standard multisource feature phenological curve are calculated, the cumulative distance corresponding to a k^{th} type of crops is φₖ, wₖ is a weight of the cumulative distance corresponding to the k^{th} type of crops, a total distance of the standard phenological curves of the crops in the corresponding phenological zones is φₛᵤₘ, and the weight of the cumulative distance corresponding to the k^{th} type of crops is determined by the total distance of the standard phenological curves of the crops in the corresponding phenological zones:

φₛᵤₘ=w₁*φ1+w₂*φ2+ . . . +wₖ*φₖ;

Distanceᵢ is set as a sum of cumulative distances between the standard phenological curves in an i^{th} phenological zone, and wᵢ is the weight of the cumulative distance corresponding to an i^{th} type of crops:

$${w}_{i} = \frac{{Distance}_{i}}{{\sum }_{i = 1} {Distance}_{i}} .$$

distance_{cp} is set as the cumulative distance between corn and peanuts, distance_{cs} is set as the cumulative distance between corn and sweet potatoes, distanceₚₛ is set as the cumulative distance between peanuts and sweet potatoes, and Distance is set as the total cumulative distance in the region:

Distance=distance_{cp}+distance_{cs}+distanceₚₛ.

When the cumulative distances between the standard phenological curves of different crops is calculated, cumulative distances between the standard phenological curves of different features reach the maximum at different times.

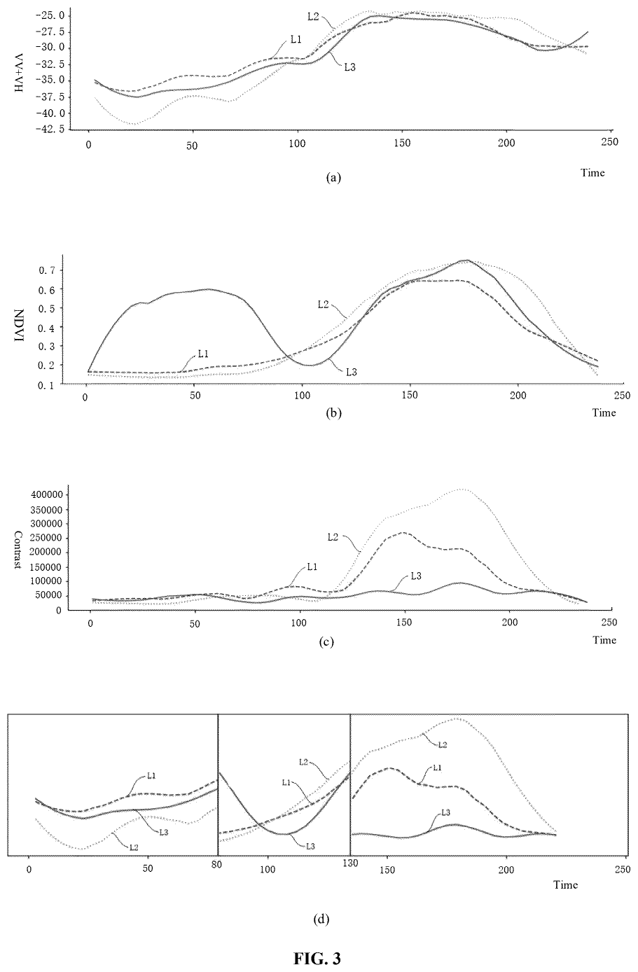

As shown in FIG. 3, L1 denotes peanuts, L2 denotes sweet potatoes, and L3 denotes corn. (1) in FIG. 3 illustrates a multisource TWDTW zone chart, with the abscissa axis being the growing time of crops (unit: day) from Mar. 1, 2024 and the vertical axis being VV+VH; (b) in FIG. 3 illustrates NDVI curves of the crops, with the abscissa axis being time (unit: day) and the vertical axis being the NDVI; (c) in FIG. 3 illustrates contrast curves, with the abscissa axis being time (unit: day) and the vertical axis being the contrast calculated by means of the near-infrared band; and in (d) in FIG. 3 the growth period of the crops is divided into three phases, and phenological curves of different features are used in the phases. Wherein, the difference in the standard phenological curve of the SAR image feature is mainly centralized in the early seeding phase (from day 0 to day 80) of the crops, the difference in the NDVI in an optical image is centralized in the growth and development phase (from day 80 to day 130) of the crops, and the difference in the texture feature calculated by means of the near-infrared band of the multi-spectral remote-sensing data is mainly centralized in the last phase of the growth period of the crops (after day 130).

Existing remote-sensing data are fully used to improve the sample generation accuracy. The multisource TWDTW algorithm provided by the invention splices standard phenological curves of different features into a standard multisource feature phenological curve with greater differences according to the difference in sensitivity of features of the crops in different growth periods, as shown by (d) in FIG. 3. When samples are generated, phenological curves to be matched are also generated according to different features in at different times.

Optionally, the crop type of the sample points under detection is determined according to the cumulative distances and the threshold ranges to obtain preliminarily classified samples, and a time series of the sample generation region is resampled to be identical with a standard time series of the crops.

Optionally, a Manhattan distance between each preliminarily classified sample and a corresponding labelled crop is calculated; if the Manhattan distance is greater than a set threshold, the preliminarily classified sample is reserved; otherwise, the preliminarily classified sample is rejected; assume the Manhattan distance is set as MD, xᵢ is a feature value of the time series of the sample generation region at a time i, yᵢ is a feature value of the standard time series at the time i and N is the number of data in the time series, the Manhattan distance between each preliminarily classified sample and the corresponding labelled crop is:

$$MD = {\sum }_{i = 1}^{N} \vert {x}_{i} - {y}_{i} \vert .$$

Optionally, before the Manhattan distance between each preliminarily classified sample and the corresponding labelled crop is calculated, the time series of the sample generation region is resampled to be identical with the standard time series of the crops.

To verify the reliability of the invention, sample generation is carried out in a target region based on field investigation points and the method provided by the invention, and sample generation results are superimposed in a map of a peanut plot where peanuts are planted for the first year. Almost all generated sample points fall within the peanut plot, indicating that the method provided by the invention has high sample generation accuracy. A sample generation experiment is further carried out by means of existing field sampling point data in the second year. If there is no field sampling data of this region, field sampling points of this region in previous years are used to generate sample points. Sample date generated by means of a limited number of field sampling points also prove that the method provided by the invention has high sample generation accuracy.

The invention provides the method for automatically generating peanut samples based on multisource remote-sensing data and growth period features, which establishes a standard multisource feature phenological curve according to SAR data, multi-spectral remote-sensing data and land cover data, calculates cumulative distances between multisource feature phenological curves of sample points under detection and the standard multisource feature phenological curve, and improves the recognition accuracy of peanuts in the early phase by machine learning, thus reducing the peanut sample acquisition difficulty and cost.

### Embodiment 2

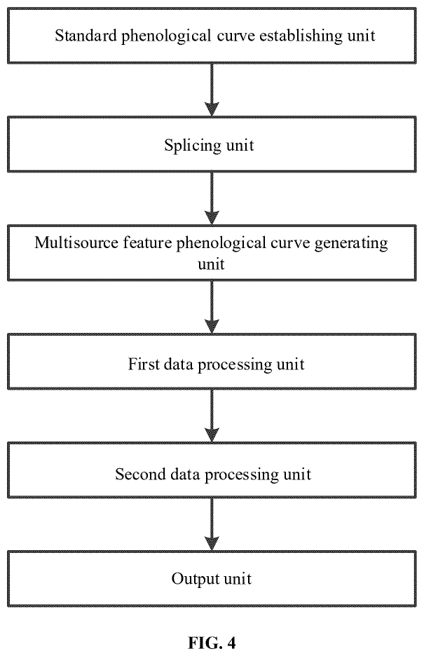

Based on the same principle as the method in Embodiment 1 of the invention, as shown in FIG. 4, this embodiment of the invention provides a system for automatically generating peanut samples based on multisource TWDTW, including a standard phenological curve establishing unit, a splicing unit, a multisource feature phenological curve generating unit, a first data processing unit, a second data processing unit and an output unit.

The standard phenological curve establishing unit is configured to establish a plurality of phenological zones according to areas of all types of crops in a region and establish standard phenological curves corresponding to features of the crops in the phenological zones according to field investigation sample point data and preprocessed remote-sensing image time series data.

The splicing unit is configured to splice the standard phenological curves of different features in the same region and time period to form a standard multisource feature phenological curve.

The multisource feature phenological curve generating unit is configured to acquire land cover data of a sample generation region, randomly generate sample points in a land plot and calculate time series data of the sample points under detection to obtain multisource feature phenological curves of the sample points under detection.

The first data processing unit is configured to calculate cumulative distances between multisource feature phenological curves of all the types of crops and the standard multisource feature phenological curve and determine threshold ranges corresponding to the cumulative distances between the multisource feature phenological curves of all the types of crops and the standard multisource feature phenological curve.

The second data processing unit is configured to calculate cumulative distances between the multisource feature phenological curves of the sample points under detection and the standard multisource feature phenological curve.

The output unit is configured to determine a crop type of the sample points under detection according to the cumulative distances and the threshold ranges to obtain sample data of the crop type.

Optionally, the remote-sensing image time series data include Synthetic Aperture Radar (SAR) data, multi-spectral remote-sensing data and land cover data.

Optionally, preprocessing the remote-sensing image time series data of the crops includes: filtering the remote-sensing image time series data, transforming a coordinate system into a world geodetic system, and resampling an azimuth resolution and a range resolution of images to 10 m; performing time series smoothing by an S-G smoothing filter algorithm to remove thermal noise; performing radiation correction; and performing topographical correction by means of DEM data.

Optionally, the features of the crops include a band feature, a texture feature and a vegetation index feature.

Optionally, calculating cumulative distances between multisource feature phenological curves of all the types of crops and the standard multisource feature phenological curve includes: setting a time series of the multisource feature phenological curves of the crops as U, a length of the time series as m and an i^{th} feature as uᵢ, and setting a time series of the standard multisource feature phenological curve as V, a length of the time series as n and a j^{th} feature as vᵢ:

U={u₁,u₂, . . . ,uₘ}^{T};

V={v₁,v₂, . . . ,vₙ}^{T};
setting d_{i, j} as a time-weighted distance between the i^{th} feature and the j^{th} feature and D_{m×n} as a distance matrix between the i^{th} feature and the j^{th} feature:

D_{m×n}=(d_{i,j})_{m×n};
setting a time weight factor as w_{i, j}, g as a gain factor and c as a distance factor, wherein the distance factor is a difference in time series length between the i^{th} feature and the j^{th} feature, c=i−j, and mc is a set ratio of series timespan:

$${d}_{i , j} = \vert {u}_{i} - {v}_{j} \vert + {w}_{i , j} ;$$

$${w}_{i , j} = \frac{1}{1 + {e}^{( - g ( c - {m}_{c} ) )}} ;$$

setting (i, j) as a node corresponding to the i^{th} feature and the j^{th} feature, (i+1, j) as a node corresponding to a (i+1)^{th} feature and the j^{th} feature, (i, j+1) as a node corresponding to the i^{th} feature and a (j+1)^{th} feature, (i+1, j+1) as a node corresponding to the (i+1)^{th} feature and the (j+1)^{th} feature and a cumulative distance between U and V at the node (i, j) as φ(i, j), searching for a minimum cumulative distance, and setting a cumulative distance at a previous node as a minimum value of (i−1, j), (i, j−1) and (i−1, j−1):

φ(i,j)=d_{i,j}+min{φ(i−1,j),φ(i−1,j−1),φ(i,j−1)};
setting a minimum cumulative distance path as L:

max{m,n}≤L≤m+n−1.

Optionally, when the cumulative distances between the multisource feature phenological curves of all the types of crops and the standard multisource feature phenological curve are calculated, the cumulative distance corresponding to a k^{th} type of crops is φₖ, wₖ is a weight of the cumulative distance corresponding to the k^{th} type of crops, a total distance of the standard phenological curves of the crops in the corresponding phenological zones is φₛᵤₘ, and the weight of the cumulative distance corresponding to the k^{th} type of crops is determined by the total distance of the standard phenological curves of the crops in the corresponding phenological zones:

φₛᵤₘ=w₁*φ1+w₂*φ2+ . . . +wₖ*φₖ;

Distanceᵢ is set as a sum of cumulative distances between the standard phenological curves in an i^{th} phenological zone, and wᵢ is the weight of the cumulative distance corresponding to an i^{th} type of crops:

$${w}_{i} = \frac{{Distance}_{i}}{{\sum }_{i = 1} {Distance}_{i}} .$$

Optionally, the crop type of the sample points under detection is determined according to the cumulative distances and the threshold ranges to obtain preliminarily classified samples, and a time series of the sample generation region is resampled to be identical with a standard time series of the crops.

Optionally, a Manhattan distance between each preliminarily classified sample and a corresponding labelled crop is calculated; if the Manhattan distance is greater than a set threshold, the preliminarily classified sample is reserved; otherwise, the preliminarily classified sample is rejected; assume the Manhattan distance is set as MD, xᵢ is a feature value of the time series of the sample generation region at a time i, yᵢ is a feature value of the standard time series at the time i and N is the number of data in the time series, the Manhattan distance between each preliminarily classified sample and the corresponding labelled crop is:

$$MD = {\sum }_{i = 1}^{N} \vert {x}_{i} - {y}_{i} \vert .$$

Optionally, before the Manhattan distance between each preliminarily classified sample and the corresponding labelled crop is calculated, the time series of the sample generation region is resampled to be identical with the standard time series of the crops.

The above embodiments are merely preferred ones of the invention and are not used to limit the invention. For those skilled in the art, various modifications and transformations may be made to the invention. Any modifications, equivalent substitutions and improvements made based on the spirit and principle of the invention should also fall within the protection scope of the invention.

What is claimed is:

1. A method for automatically generating peanut samples based on multisource TWDTW, comprising:
establishing a plurality of phenological zones according to planting structures of all types of crops in a region, and establishing standard phenological curves corresponding to features of the crops in the phenological zones according to field investigation sample point data and preprocessed remote-sensing image time series data, wherein the remote-sensing image time series data comprise SAR data, multi-spectral remote-sensing data and land cover data, and the features of the crops comprise a band feature, a texture feature and a vegetation index feature;
splicing the standard phenological curves of different features, within a growth period, in the same region and time period to form a standard multisource feature phenological curve, wherein the growth period of the crops is divided into three phases, and the phenological curves of different features are used in the phases; a difference in the standard phenological curve of an SAR image feature is mainly centralized in an early seeding phase of the crops, a difference in an NDVI in an optical image is centralized in a growth and development phase of the crops, and a difference in a texture feature calculated by means of a near-infrared band of the multi-spectral remote-sensing data is mainly centralized in a last phase of the growth period of the crops; the standard phenological curve of the SAR image feature in the early seeding phase of the crops, the standard phenological curve of the NDVI in the optical image in the growth and development phase of the crops and the standard phenological curve of the texture feature calculated by means of the near-infrared band of the multi-spectral remote-sensing data in the last phase of the growth period of the crops are spliced to form the complete standard multisource feature phenological curve;
acquiring land cover data of a sample generation region, randomly generating sample points in a land plot, and calculating time series data of the sample points under detection to obtain multisource feature phenological curves of the sample points under detection;
calculating cumulative distances between multisource feature phenological curves of all the types of crops and the standard multisource feature phenological curve, and determining threshold ranges corresponding to the cumulative distances between the multisource feature phenological curves of all the types of crops and the standard multisource feature phenological curve;
calculating cumulative distances between the multisource feature phenological curves of the sample points under detection and the standard multisource feature phenological curve; and
determining a crop type of the sample points under detection according to the cumulative distances and the threshold ranges to obtain preliminarily classified samples, resampling a time series of the sample generation region to be identical with a standard time series of the crops, and calculating a Manhattan distance between each preliminarily classified sample and a corresponding labelled crop; if the Manhattan distance is greater than a set threshold, reversing the preliminarily classified sample; otherwise, rejecting the preliminarily classified sample, wherein assume the Manhattan distance is set as MD, xᵢ is a feature value of the time series of the sample generation region at a time i, yᵢ is a feature value of the standard time series at the time i and N is the number of data in the time series, the Manhattan distance between each preliminarily classified sample and the corresponding labelled crop is:
$$MD = {\sum }_{i = 1}^{N} \vert {x}_{i} - {y}_{i} \vert .$$

2. The method for automatically generating peanut samples based on multisource TWDTW according to claim 1, wherein preprocessing the remote-sensing image time series data of the crops comprises: filtering the remote-sensing image time series data, transforming a coordinate system into a world geodetic system, and resampling an azimuth resolution and a range resolution of images to 10 m; performing time series smoothing by an S-G smoothing filter algorithm to remove thermal noise; performing radiation correction; and performing topographical correction by means of DEM data.

3. The method for automatically generating peanut samples based on multisource TWDTW according to claim 1, wherein calculating cumulative distances between multisource feature phenological curves of all the types of crops and the standard multisource feature phenological curve comprises: setting a time series of the multisource feature phenological curves of the crops as U, a length of the time series as m and an i^{th} feature as uᵢ, and setting a time series of the standard multisource feature phenological curve as V, a length of the time series as n and a j^{th} feature as vᵢ:
U={u₁,u₂, . . . ,uₘ}^{T};
V={v₁,v₂, . . . ,vₙ}^{T};
setting d_{i, j} as a time-weighted distance between the i^{th} feature and the j^{th} feature and D_{m×n} as a distance matrix between the i^{th} feature and the j^{th} feature:
D_{m×n}=(d_{i,j})_{m×n};
setting a time weight factor as w_{i, j}, g as a gain factor and c as a distance factor, wherein the distance factor is a difference in time series length between the i^{th} feature and the j^{th} feature, c=i−j, and m, is a set ratio of series timespan:
$${d}_{i , j} = \vert {u}_{i} - {v}_{j} \vert + {w}_{i , j} ;$$
$${w}_{i , j} = \frac{1}{1 + {e}^{( - g ( c - {m}_{c} ) )}} ;$$
setting (i, j) as a node corresponding to the i^{th} feature and the j^{th} feature, (i+1, j) as a node corresponding to a (i+1)^{th} feature and the j^{th} feature, (i, j+1) as a node corresponding to the i^{th} feature and a (j+1)^{th} feature, (i+1, j+1) as a node corresponding to the (i+1)^{th} feature and the (j+1)^{th} feature and a cumulative distance between U and V at the node (i, j) as φ(i, j), searching for a minimum cumulative distance, and setting a cumulative distance at a previous node as a minimum value of (i−1, j), (i, j−1) and (i−1, j−1):
φ(i,j)=d_{i,j}+min{φ(i−1,j),φ(i−1,j−1),φ(i,j−1)};
setting a minimum cumulative distance path as L:
max{m,n}≤L≤m+n−1.

4. The method for automatically generating peanut samples based on multisource TWDTW according to claim 1, wherein when the cumulative distances between the multisource feature phenological curves of all the types of crops and the standard multisource feature phenological curve are calculated, the cumulative distance corresponding to a k^{th} type of crops is φₖ, wₖ is a weight of the cumulative distance corresponding to the k^{th} type of crops, a total distance between of standard phenological curves of the crops in the corresponding phenological zones is φₛᵤₘ, and the weight of the cumulative distance corresponding to the k^{th} type of crops is determined by the total distance of the standard phenological curves of the crops in the corresponding phenological zones:
φₛᵤₘ=w₁*φ₁+w₂*φ₂+ . . . +wₖ*φₖ;
Distanceᵢ is set as a sum of cumulative distances between the standard phenological curves in an i^{th} phenological zone, and wᵢ is the weight of the cumulative distance corresponding to an i^{th} type of crops:
$${w}_{i} = \frac{{Distance}_{i}}{{\sum }_{i = 1} {Distance}_{i}} .$$

5. A system for automatically generating peanut samples based on multisource TWDTW, comprising a standard phenological curve establishing unit, a splicing unit, a multisource feature phenological curve generating unit, a first data processing unit, a second data processing unit and an output unit, wherein:
the standard phenological curve establishing unit is configured to establish a plurality of phenological zones according to planting structures of all types of crops in a region and establish standard phenological curves corresponding to features of the crops in the phenological zones according to field investigation sample point data and preprocessed remote-sensing image time series data, wherein the remote-sensing image time series data comprise SAR data, multi-spectral remote-sensing data and land cover data, and the features of the crops comprise a band feature, a texture feature and a vegetation index feature;
the splicing unit is configured to splice the standard phenological curves of different features, within a growth period, in the same region and time period to form a standard multisource feature phenological curve, wherein the growth period of the crops is divided into three phases, and the phenological curves of different features are used in the phases; a difference in the standard phenological curve of an SAR image feature is mainly centralized in an early seeding phase of the crops, a difference in an NDVI in an optical image is centralized in a growth and development phase of the crops, and a difference in a texture feature calculated by means of a near-infrared band of the multi-spectral remote-sensing data is mainly centralized in a last phase of the growth period of the crops; the standard phenological curve of the SAR image feature in the early seeding phase of the crops, the standard phenological curve of the NDVI in the optical image in the growth and development phase of the crops and the standard phenological curve of the texture feature calculated by means of the near-infrared band of the multi-spectral remote-sensing data in the last phase of the growth period of the crops are spliced to form the complete standard multisource feature phenological curve;
the multisource feature phenological curve generating unit is configured to acquire land cover data of a sample generation region, randomly generate sample points in a land plot and calculate time series data of the sample points under detection to obtain multisource feature phenological curves of the sample points under detection;
the first data processing unit is configured to calculate cumulative distances between multisource feature phenological curves of all the types of crops and the standard multisource feature phenological curve and determine threshold ranges corresponding to the cumulative distances between the multisource feature phenological curves of all the types of crops and the standard multisource feature phenological curve;
the second data processing unit is configured to calculate cumulative distances between the multisource feature phenological curves of the sample points under detection and the standard multisource feature phenological curve;
the output unit is configured to determine a crop type of the sample points under detection according to the cumulative distances and the threshold ranges to obtain preliminarily classified samples, resample a time series of the sample generation region to be identical with a standard time series of the crops, and calculate a Manhattan distance between each preliminarily classified sample and a corresponding labelled crop, wherein if the Manhattan distance is greater than a set threshold, the preliminarily classified sample is reversed; otherwise, the preliminarily classified sample is rejected; assume the Manhattan distance is set as MD, xᵢ is a feature value of the time series of the sample generation region at a time i, yᵢ is a feature value of the standard time series at the time i and N is the number of data in the time series, the Manhattan distance between each preliminarily classified sample and the corresponding labelled crop is:
$$MD = {\sum }_{i = 1}^{N} \vert {x}_{i} - {y}_{i} \vert .$$
